(19) United States
(12) Patent Application Publication
(10) Pub. No.: US 2013/0201460 A1
(43) Pub. Date: Aug. 8, 2013

(54) EXPOSURE METHOD, EXPOSURE APPARATUS AND CLEANING METHOD

(71) Applicant: NIKON CORPORATION, Tokyo (JP)

(72) Inventor: Yasuhisa TANI, Machida-shi (JP)

(73) Assignee: NIKON CORPORATION, Tokyo (JP)

(21) Appl. No.: 13/742,941

(22) Filed: Jan. 16, 2013

Related U.S. Application Data
(63) Continuation of application No. PCT/JP2011/066498, filed on Jul. 20, 2011.

(30) Foreign Application Priority Data
Jul. 20, 2010 (JP) 2010-163112

(51) Int. Cl. G03F 7/20

(52) U.S. Cl. CPC G03F 7/70341
USPC 355/30

(57) ABSTRACT

There is provided an exposure method for exposing a substrate by using an immersion exposure apparatus provided with a water-repellent area which has a water repellent film and which is at least a part of an area configured to make contact with a liquid so as to irradiate an exposure light onto the substrate via the liquid, the exposure method including: a measuring step of performing a measurement via the liquid with respect to at least a part of the water-repellent area having the water repellent film; and an exposure step of irradiating the exposure light onto the substrate via the liquid. In the measuring step and/or the exposure step, oxidation-reduction potential of the liquid is controlled to a predetermined value.

### CROSS REFERENCE TO RELATED APPLICATION

This application claims the benefit of priorities of Japanese Patent Application No. 2010-163112 filed on Jul. 20, 2010 and International Patent Application No. PCT/JP2011/066,498 filed on Jul. 20, 2011, and the disclosures of Japanese Patent Application No. 2010-163112 and International Patent Application No. PCT/JP2011/066498 are incorporated herein by reference in their entities.

### FIELD

The present teaching relates to an exposure method and exposure apparatus configured to expose a substrate with a pattern via a projection optical system and a liquid, and a cleaning method for cleaning a part of the exposure apparatus.

### BACKGROUND ART

In a photolithography step in a production process for producing a microdevice such as a semiconductor device, a liquid crystal display device, etc., a mask is irradiated with an exposure light (exposure light beam) to project a pattern formed on the mask onto a photosensitive substrate to thereby expose the substrate. In the photography step, further miniaturization is required of the pattern to be formed on the substrate so as to respond to the demand for highly densified microdevices in the recent years. As one of the means for realizing such a miniaturization of the pattern, a liquid immersion method is proposed, as disclosed in the pamphlet of International Publication No. WO 99/49504, for filling an optical path space of the exposure light between a projection optical system and the substrate with a liquid, and for exposing the substrate via the liquid.

Since the substrate as an object to be exposed (exposure object) is placed on a stage of an exposure apparatus, an area is present, on the stage, which makes contact with the liquid for immersion (immersion liquid). The area which contacts with the liquid (liquid contact area) has a surface property as less wettable by the immersion liquid so as to prevent any liquid from remaining in the area. In a case that the liquid is pure water (purified water), the liquid contact area is water-repellent.

The liquid contact area contacting with the immersion liquid in the exposure apparatus is exemplified by a portion or part on a positioning mark as a reference serving as the coordinate positions for the mask and/or the substrate and a portion or part located around the positioning mark. Further, a measurement window for measuring the light amount and/or uneven illuminance of the exposure light, the aberration performance of an optical system, etc. are also included in the liquid contact area which makes contact with the immersion liquid. Generally, a positioning mark is formed by a pattern of a chromium film, while a measurement window is produced by providing a chromium film (light-shielding film) on a surface of a glass plate and then by forming a pinhole in the chromium film. The reason for forming the positioning mark and the measurement window with the chromium film in such a manner is that the chromium film is easily processed with high degree of fineness and precision.

The immersion liquid is supplied onto the positioning mark and measurement window formed with the chromium films, and measurement is performed, via the liquid, regarding the positioning mark, the light amount of the exposure light, etc. An area including the positioning mark and the measurement window is provided with a water repellent film which is disposed on the chromium film so that the surface of the area including the positioning mark and the measurement window is water-repellent.

In an exposure using the liquid immersion method is performed in a state that a surface of the substrate is coated with a photosensitive material. In some cases, the surface of the photosensitive material (photoresist) is coated with a top coat exhibiting water repellency or a photoresist having the water repellency is used. When such a top coat or photoresist makes contact with the liquid, any organic contaminant is eluted into the liquid in some cases. Further, there also arises such a problem that the chromium film forming the above-described positioning mark and measurement window degrades or disappears. The immersion liquid passes through the above-described water repellent film and comes into contact with the chromium film, which in turn causes a part or portion of the chromium film to elute into the immersion liquid, resulting in contaminating the immersion liquid.

The contaminant in the liquid then adheres to the liquid contact area contacting with the immersion liquid in the exposure apparatus. In particular, the eluted chromium is changed through hydration into hydrophilic chromium hydroxide and chromic oxide, and adheres to the liquid contact area. When these organic contaminant and chromium-derived contaminant adhere to the area including the water-repellent positioning mark and the water-repellent measurement window, then the area cannot maintain the water repellency, which in turn gives rise to such a problem as occurrence of water mark, etc., due to the remaining liquid. Accordingly, there is a fear that the positioning and measuring accuracies might be lowered.

### SUMMARY

The present teaching is made in view of such a situation, an object of which is to provide an exposure method, a cleaning method and an exposure apparatus which are capable of cleaning the liquid contact area.

According to a first aspect, there is provided an exposure method for exposing a substrate by using an immersion exposure apparatus provided with a water-repellent area which has a water repellent film therein and which is at least a part of an area configured to make contact with a liquid so as to irradiate an exposure light onto the substrate via the liquid, the exposure method including: a measuring step of performing a measurement via the liquid with respect to at least a part of the water-repellent area having the water repellent film; and an exposure step of irradiating the exposure light onto the substrate via the liquid; wherein in the measuring step and/or the exposure step, oxidation-reduction potential of the liquid is controlled to a predetermined value.

According to a second aspect, there is provided a cleaning method for cleaning a water-repellent area in an immersion exposure apparatus configured to expose a substrate by irradiating an exposure light onto the substrate via a liquid, the water-repellent area having a water repellent film therein and being at least a part of an area configured to make contact with the liquid, the cleaning method including using the liquid of which oxidation-reduction potential is increased so as to clean the water-repellent area having the water repellent film.

According to a third aspect, there is provided an exposure apparatus configured to expose a substrate by projecting an image of a pattern onto the substrate via a liquid, the exposure apparatus including: a stage configured to hold the substrate; an optical element configured to form the image of the pattern on the substrate; a liquid supply section configured to supply the liquid onto the stage; and an oxidation-reduction potential control section configured to control oxidation-reduction potential of the liquid to a predetermined value; wherein at least a part of a surface, of the stage, configured to make contact with the liquid is a water-repellent area having a water repellent film therein.

According to a fourth aspect, there is provided an exposure method including: a measuring step of irradiating a light onto a measuring member, which has a base member and a pattern formed of a metal and disposed on the base member, in a state that the measuring member makes contact with a liquid; and an exposure step of irradiating an exposure light onto a substrate via the liquid; wherein in the measuring step, the liquid has oxidation-reduction potential which is lower than that of pure water.

According to a fifth aspect, there is provided an exposure method for exposing a substrate by using an immersion exposure apparatus provided with a water-repellent area which has a water repellent film therein and which is at least a part of an area configured to make contact with a liquid so as to irradiate an exposure light onto the substrate via the liquid, the exposure method including: a measuring step of performing a measurement via the liquid with respect to at least a part of the water-repellent area having the water repellent film; and an exposure step of irradiating the exposure light onto the substrate via the liquid; wherein in the measuring step, oxidation-reduction potential of the liquid is decreased.

According to a sixth aspect, there is provided an exposure method for exposing a substrate by using an immersion exposure apparatus provided with a water-repellent area which has a water repellent film therein and which is at least a part of an area configured to make contact with a liquid so as to irradiate an exposure light onto the substrate via the liquid, the exposure method including: a measuring step of performing a measurement via the liquid with respect to at least a part of the water-repellent area having the water repellent film; and an exposure step of irradiating the exposure light onto the substrate via the liquid; wherein the measuring step uses a liquid of which oxidation-reduction potential has been controlled so as to suppress elution of metal.

The term “Oxidation-Reduction Potential (ORP)” refers to a criterion or standard which quantitatively indicates the readiness of a substance to emit electrons (oxidation power), or the readiness of a substance to receive electrons (reduction power). A liquid having a high oxidation-reduction potential has a strong oxidation power and is capable of decomposing and removing a contaminant. On the other hand, a liquid having a low oxidation-reduction potential has a strong reduction power and is capable of suppressing a metal from eluting into the liquid. The term “0 V” is defined as an electrode potential provided that the partial pressure of hydrogen gas is 1 atmosphere and the activity of hydrogen ion is 1 (this is referred to as the standard hydrogen electrode).

In the present description, the term “increase the oxidation-reduction potential of the liquid” and the term “decrease the oxidation-reduction potential of the liquid” mean such a control that the oxidation-reduction potential becomes higher and, likewise, such a control that the oxidation-reduction potential becomes lower, as compared with a liquid in a state that any control is not performed therefor regarding the oxidation-reduction potential.

### BRIEF DESCRIPTION OF THE DRAWINGS

FIG. 1 is a view schematically showing the configuration of an exposure apparatus according to an embodiment;

FIG. 2 is a top view of a substrate stage provided on the exposure apparatus according to the embodiment;

FIG. 3 is a cross-sectional view of an uneven illuminance sensor provided on the exposure apparatus according to the embodiment;

FIG. 4 is a view schematically showing the configuration of an oxidation-reduction potential (ORP) control section provided on the exposure apparatus according to the embodiment o;

FIG. 5 is a flowchart showing an exposure method and a cleaning method according to the embodiment; and

FIG. 6 is a cross-sectional view of an uneven illuminance sensor provided on an exposure apparatus according to another embodiment.

### DESCRIPTION OF THE EMBODIMENTS

In the following, embodiments of an exposure apparatus, an exposure method and a cleaning method will be explained with reference to the drawings.

### First Embodiment

### Exposure Apparatus

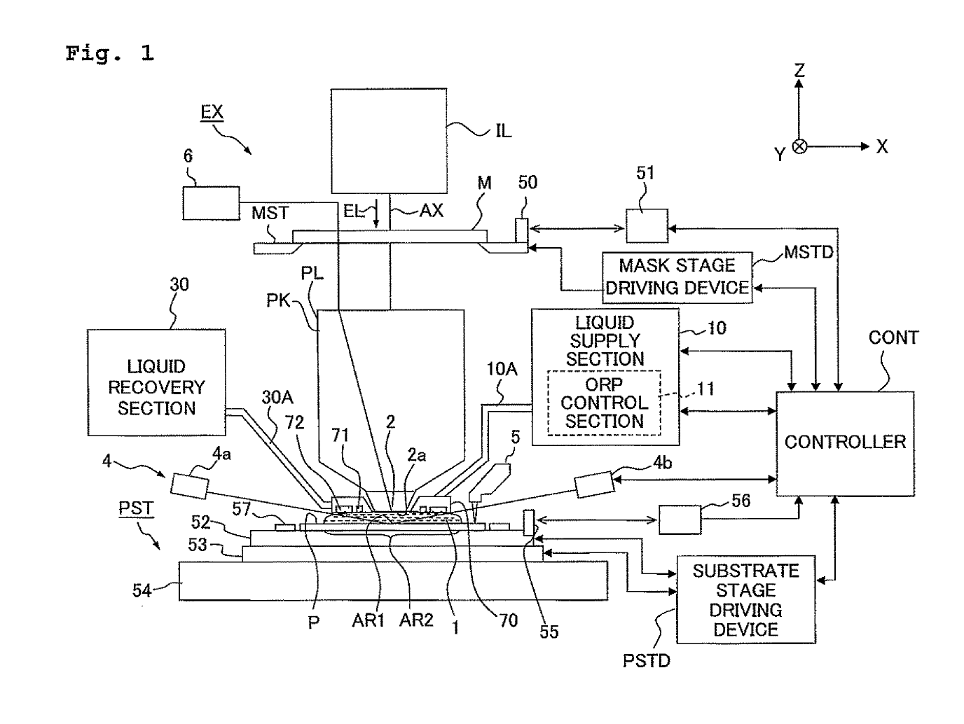

In FIG. 1, an exposure apparatus EX of the first embodiment mainly includes a mask stage MST which is movable while holding a mask M; a substrate stage PST which holds a substrate P; an illumination optical system IL which illuminates the mask M held on the mask stage MST with an exposure light EL; a projection optical system PL which projects an image of the pattern (pattern image) of the mask M illuminated with the exposure light EL onto the substrate P held on the substrate stage PST to expose the substrate with the pattern image; and a controller CONT which integrally controls the operations of the exposure apparatus EX as a whole.

The exposure apparatus EX is an immersion exposure apparatus to which the liquid immersion method is applied in order that the exposure wavelength is substantially shortened to improve the resolution and the depth of focus is substantially widened. The exposure apparatus EX includes a liquid supply section 10 which supplies a liquid 1 onto the substrate P; a liquid recovery section 30 which recovers the liquid 1 on the substrate P; and a nozzle member 70 to which the liquid supply section 10 and the liquid recovery section 30 are connected. The liquid supply section 10 and the liquid recovery section 30 are connected to the nozzle member 70 via a supply tube 10A and a recovery tube 30A, respectively. The nozzle member 70 is arranged closely and adjacently to an optical element (lens) 2 provided at an end portion of the projection optical system PL, and the nozzle member 70 has a supply port 71 via which a liquid is supplied, and a recovery port 72 via which the liquid is recovered. The liquid supply section 10 supplies the liquid 1 onto the substrate P via the nozzle member 70, whereas the liquid recovery section 30 recovers the liquid 1 via the nozzle member 70. In the first embodiment, pure water or purified water is used as the liquid 1. The exposure apparatus EX forms a liquid immersion area AR2, including a projection area AR1 of the projection optical system PL on the substrate P, locally on the substrate P with the liquid 1 supplied from the liquid supply section 10, while transferring the pattern image of the mask M onto the substrate P. The exposure apparatus EX exposes the substrate P by filling a space between the optical element 2 which is disposed at the end portion of the projection optical system PL and a surface (exposure surface) of the substrate P with the liquid 1, and by projecting the pattern image of the mask M onto the substrate P via the projection optical system PL and the liquid 1 filled in the space between the projection optical system PL and the substrate P.

Here, the first embodiment is explained with an example of a case using a scanning exposure apparatus (so-called scanning stepper), as the exposure apparatus EX, which exposes the substrate P with the pattern formed on the mask M while synchronously moving the mask M and the substrate P in mutually different orientations (opposite directions) in a scanning direction (predetermined direction). In the following explanation, an X-axis direction is the synchronous movement direction (scanning direction or predetermined direction) of the mask M and the substrate P in a horizontal plane; a Y-axis direction (non-scanning direction) is a direction perpendicular to the X-axis direction in the horizontal plane; and a Z-axis direction is a direction coincident with an optical axis AX of the projection optical system PL and perpendicular to the X-axis and Y-axis directions. Further, θX direction, θY direction and θZ direction are rotational directions about the X-axis, the Y-axis and the Z-axis, respectively. Note that the term “substrate” described herein includes a semiconductor wafer coated with a top coat including a photoresist (photosensitive agent) and a water repellent fluorocarbon; and the term “mask” includes a reticle having a device pattern which is formed on the reticle and which is to be subjected to reduction projection onto the substrate.

The illumination optical system IL is configured to illuminate the mask M held by the mask stage MST with the exposure light EL, and has an exposure light source, an optical integrator which uniformizes the illuminance of the light flux radiated from the exposure light source, a condenser lens which condenses the exposure light EL from the optical integrator, a relay lens system, a variable field stop which defines a slit-shaped illumination area on the mask M brought about by the exposure light EL, etc. The illumination optical system IL illuminates a predetermined illumination area on the mask M with the exposure light EL having a uniform illuminance distribution. Those usable as the exposure light beam EL irradiated from the illumination optical system IL include, for example, emission lines in the ultraviolet region (g-line, h-line, i-line) radiated, for example, from a mercury lamp, far ultraviolet light beams (DUV light beams) such as the KrF excimer laser beam (wavelength: 248 nm), and vacuum ultraviolet light beams (VUV light beams) such as the ArF excimer laser beam (wavelength: 193 nm) and the F₂ laser beam (wavelength: 157 nm). In this embodiment, the ArF excimer laser beam is used. As described above, the liquid 1 is pure water in this embodiment, through which even the ArF excimer laser beam as the exposure light beam EL is transmissive. Those also capable of being transmitted through pure water include the emission line in the ultraviolet region (g-line, h-line, i-line) and the far ultraviolet light beam (DUV light beam) such as the KrF excimer laser beam (wavelength: 248 nm).

The mask stage MST is configured to hold the mask M, and is two-dimensionally movable in the plane perpendicular to the optical axis AX of the projection optical system PL, i.e., in the XY plane, and it is finely rotatable in the θZ direction. The mask stage MST is driven by a mask stage-driving unit MSTD such as a linear motor. The mask stage-driving unit MSTD is controlled by the controller CONT. A reflecting mirror 50 is provided on the mask stage MST. A laser interferometer 51 is provided at a position facing or opposite to the reflecting mirror 50. The position in the two-dimensional direction and the angle of rotation of the mask M on the mask stage MST are measured in real-time by the laser interferometer 51; and the result of the measurement is outputted to the controller CONT. The controller CONT drives the mask stage-driving unit MSTD based on the result of the measurement obtained by the laser interferometer 51 to thereby position the mask M supported on the mask stage MST.

The projection optical system PL is configured to expose the substrate P by projecting the pattern of the mask M at a predetermined projection magnification β, and is constructed of a plurality of optical elements including the optical element (lens) 2 provided at the end portion thereof on the side of the substrate P. These optical elements are held by a barrel PK. In the first embodiment, the projection optical system PL is a reduction system having the projection magnification β which is, for example, ¼ or ⅕. Note that the projection optical system PL can be any one of the 1× magnification system and the magnifying system. Further, the optical element 2 which is disposed at the end portion of the projection optical system PL of the first embodiment is provided to be removable (interchangeable, exchangeable) with respect to the barrel PK. Furthermore, the optical element 2 which is disposed at the end portion is exposed from the barrel PK, and the liquid 1 of the liquid immersion area AR2 makes contact with the optical element 2. By virtue of this, the barrel PK made of a metal is prevented from corrosion and the like.

The optical element 2 is formed of calcium fluoride. Since calcium fluoride has high affinity for water, it is possible to allow the liquid 1 to make tight contact with the substantially entire surface of a liquid contact surface 2a of the optical element 2. Namely, since the liquid 1 (water) having a high affinity for the liquid contact surface 2a of the optical element 2 is supplied in the first embodiment, it is possible to secure a high adhesion between the liquid 1 and the liquid contact surface 2a of the optical element 2. Note that the optical element 2 can be silica glass which has high affinity for water. Further, it is also possible to perform a hydrophilic (lyophilic) treatment for the liquid contact surface 2a of the optical element 2 so as to further increase the affinity for the liquid 1.

Furthermore, the exposure apparatus EX has a focus detection system 4. The focus detection system 4 includes a light-emitting section 4a and a light-receiving section 4b. The focus detection system 4 radiates a detection light (detection light beam) in an oblique direction from the light-emitting section 4a through the liquid 1 onto the surface (exposure surface) of the substrate P, and the focus detection system 4 allows a reflected light (reflected light beam) from the substrate P to be received by the light-receiving section 4b through the liquid 1. Accordingly, the controller CONT controls the operation of the focus detection system 4; and the controller CONT detects a position (focus position) in the Z-axis direction of the surface of the substrate P, with respect to a predetermined reference surface, based on the light receiving result of the light receiving portion 4b. Further, the controller CONT is also capable of determining the posture or attitude of the substrate P in the direction of inclination by determining the respective focus positions at a plurality of points on the surface of the substrate P respectively. As the configuration of the focus detecting system 4, it is possible to use the configuration disclosed, for example, in Japanese Patent Application Laid-open No. 8-37149.

The substrate stage PST is configured to hold the substrate P, and includes a Z stage 52 which holds the substrate P via a substrate holder, an X-Y stage 53 which holds the Z stage 52, and a base 54 which holds the X-Y stage 53. The substrate stage PST is driven by a substrate stage driving device PSTD such as a linear motor, etc. The substrate stage driving device PSTD is controlled by the controller CONT. Further, it goes without saying that the Z stage and the X-Y stage can be provided integrally as one body. By driving the X-Y stage 53 of the substrate stage PST, the position of the substrate P in the X-Y direction (the position in a direction substantially parallel to the image plane of the projection optical system PL) is controlled.

A reflecting mirror 55 is provided on the substrate stage PST (the Z stage 52). Further, a laser interferometer 56 is provided at a position opposite to or facing the reflecting mirror 55. The position in the two-dimensional direction and the angle of rotation of the substrate P on the substrate stage PST are measured in real-time by the laser interferometer 56; and a result of the measurement is outputted to the controller CONT. The controller CONT drives the X-Y stage 53 via the substrate stage-driving device PSTD based on the result of the measurement of the laser interferometer 56 to thereby position the substrate P, held by the substrate stage PST, in the X-axis direction and the Y-axis direction.

Further, the controller CONT drives the Z stage 52 of the substrate stage PST via the substrate stage driving device PSTD to thereby control the position (focus position) in the Z-axis direction and positions in the θX and θY directions of the substrate P held by the Z stage 52. Namely, the Z stage 52 operates according to a command from the controller CONT based on the detection result of the focus detection system 4, and controls the focus position (Z position) and inclination angle of the substrate P so that the surface (exposure surface) of the substrate P is adjusted to match the image plane which is formed via the projection optical system PL and the liquid 1.

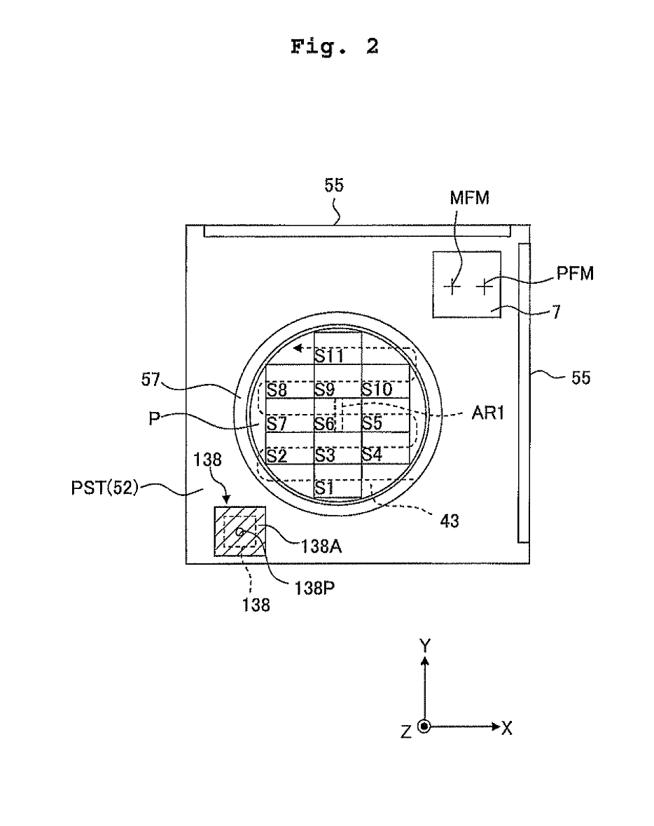

As appreciated from FIG. 2, an auxiliary plate 57 is provided on the substrate stage PST (Z stage 52) so that the substrate P is surrounded thereby. The auxiliary plate 57 has a flat surface which has approximately the same height as that of the surface of the substrate P held by the substrate holder. In this arrangement, a gap of about 0.1 to 2 mm is provided between the auxiliary plate 57 and the edge of the substrate P. However, the liquid 1 scarcely flows into the gap owing to the surface tension of the liquid 1. Even in a case that any portion in the vicinity of the circumferential edge of the substrate P is subjected to the exposure, the liquid 1 can be retained under the projection optical system PL by the aid of the auxiliary plate 57.

A substrate alignment system 5, which detects an alignment mark formed on the substrate P or a reference mark provided on the Z stage 52, is provided in the vicinity of the end portion of the projection optical system PL. A mask alignment system 6, which detects a reference mark provided on the Z stage 52 via the mask M and the projection optical system PL, is provided in the vicinity of the mask stage MST. A configuration, which is disclosed, for example, in Japanese Patent Application Laid-open No. 4-65603, can be used as the configuration of the substrate alignment system 5; and a configuration, which is disclosed, for example, in Japanese Patent Application Laid-open No. 7-176468, can be used as the configuration of the mask alignment system 6.

The liquid supply section 10 includes a tank which accommodates the liquid 1, a temperature adjustment mechanism for the liquid 1, a pressure pump, etc., and the liquid supply operation of the liquid supply section 10 is controlled by the controller CONT. The liquid supply section is configured to supply, onto the substrate P, the liquid 1 of which temperature is adjusted by the temperature adjusting mechanism to be approximately the same (for example, 23 degrees Celsius) as the temperature inside a chamber in which the apparatus is accommodated. Further, the controller CONT can control a liquid supply amount per unit time for the substrate P by the liquid supply section 10.

Further, the liquid supply section 10 is provided with an oxidation-reduction potential (ORP) control section 11 which is disposed inside the liquid supply section 10, and the liquid supply section 10 is capable of controlling the oxidation-reduction potential of the liquid 1 to be supplied. The controller CONT controls the operation of the oxidation-reduction potential (ORP) control section 11. Further, the pure water (the liquid) which is supplied from the liquid supply section 10 can have a transmission factor of not less than 99%/mm with respect to the exposure light EL; and, in this case, it is desirable to suppress TOC (Total Organic Carbon) to be less than 3 ppb, wherein TOC indicates the total amount of carbon in an organic compound which is included among carbon compounds dissolved in pure water. The control performed by the oxidation-reduction potential (ORP) control section 11 will be described in detail later in terms of the content or subject thereof.

The liquid recovery section 30 includes, for example, a suction device such as a vacuum pump, etc.; a tank which accommodates the recovered liquid 1; and the like. The liquid recovery operation of the liquid recovery section 30 is controlled by the controller CONT. The controller CONT is capable of controlling a liquid recovery amount per unit time by the liquid recovery section 30.

As shown in FIG. 2, a reference member 7 is provided at one corner of the Z stage 52. A reference mark PFM to be detected by the substrate alignment system 5 and a substrate mark MFM to be detected by the mask alignment system 6 are arranged in a predetermined positional relationship on the reference member 7. Since the reference mark PFM and the substrate mark MFM are fine and minute marks of high precision, the reference mark PFM and the substrate mark MFM are each formed as a pattern of a chromium film. Further, a surface of the reference member 7 is substantially flat, and thus functions also as a reference surface for the focus detection system 4. Furthermore, it is also possible to provide, on the Z stage 52, the reference surface for the focus detection system 4 separately from the reference member 7. Furthermore, it is possible to provide the reference member 7 and the auxiliary plate 57 integrally as one body.

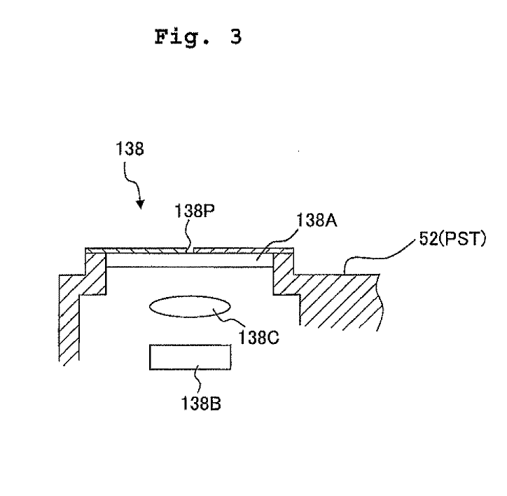

Moreover, a plate member (upper plate) 138A is provided is provided on the Z stage 52. The plate member 138A constitutes a part of an uneven illuminance sensor 138 which receives the light irradiating the image plane side (the side of the substrate P) via the projection optical system PL. As appreciated from FIG. 3, the plate member 138A has a chromium-containing thin film (light-shielding film) 138B which is formed by patterning on the surface of the glass plate and in which a pinhole 138P is formed at a central portion thereof.

In the first embodiment, the uneven illuminance sensor 138 measures the illuminance (intensity) of the exposure light, which is irradiated onto the image plane side via the projection optical system PL, at a plurality of positions so as to measure the uneven illuminance (illuminance distribution) of the exposure light irradiated onto the image plane side of the projection optical system PL, as disclosed in Japanese Patent Application Laid-Open No. 57-117238. As shown in FIG. 3, the uneven illuminance sensor 138 is provided in the substrate stage PST (the Z stage 52). The uneven illuminance sensor 138 has the plate member 138A formed by patterning the light-shielding film on a surface of the glass plate and having the pinhole 138P formed at the central portion thereof; an optical system 138C which is embedded inside the Z stage 52 and onto which a light passing through the pinhole 138P is irradiated; and a light receiving element (light receiving system) 138E which receives the light passing through the optical system 138C. Further, it is also possible to provide, for example, a relay optical system between the optical system 138C and the light receiving element 138B, and to arrange the light receiving element 138B at the outside of the Z stage 52.

Further, it is possible to provide, on the substrate stage PST, not only the uneven illuminance sensor, but also another sensor which receives the exposure light, transmitted via the projection optical system PL and the liquid, via a pinhole (light transmission portion) formed in a chromium film such as an irradiation amount monitor as disclosed in Japanese Patent Application Laid-Open No. 11-16816, a spatial image measuring sensor disclosed in Japanese Patent Application Laid-Open No. 2002-14005 for measuring imaging characteristics, etc., and the like.

The areas which make contact with the liquid 1 on the Z stage 52, such as the auxiliary plate 57, the reference member 7, the plate member (upper plate) 138A of the uneven illuminance sensor 138, etc. are each processed such that a surface of each of the areas is less wettable by the liquid 1. In the first embodiment, since pure water is used as the liquid 1, these areas are processed (treated) to have water repellency and to be less likely to give rise to any remaining liquid after the measurement. Specifically, a water repellent film containing a fluororesin is provided on the surfaces of the auxiliary plate 57, the reference member 7, the plate member (upper plate) 138A and the like such that the surfaces have a contact angle with respect to pure water of, for example, 100 degrees to 115 degrees. With respect to the reference member 7 and the plate member (upper plate) 138A, the water repellent film is provided on the chromium film. The material of the water repellent film is exemplified by fluororesins such as Cytop (trade name), Teflon (trade name), and the like.

### [Oxidation-Reduction Potential (ORP) Control Section]

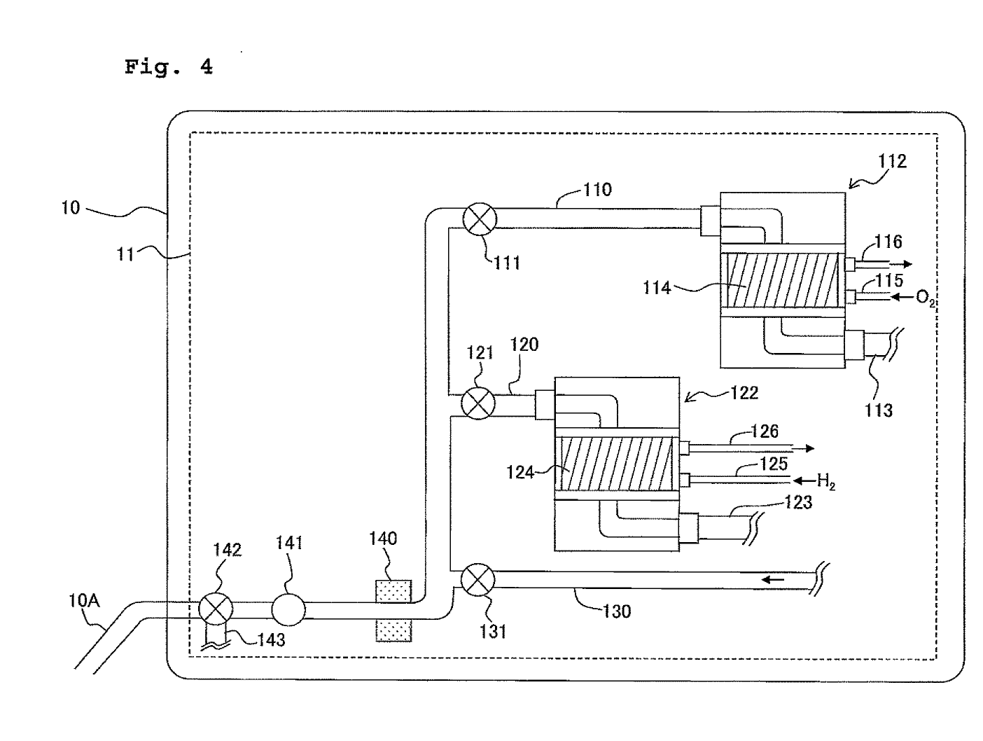

The oxidation-reduction potential (ORP) control section 11 arranged inside the liquid supply section 10 will be explained with reference to FIG. 4. The oxidation-reduction potential (ORP) control section 11 controls the oxidation-reduction potential of the liquid 1, which is supplied to the liquid immersion area AR2 via the supply tube 10A and the nozzle member 70, to a predetermined value. The oxidation-reduction potential (ORP) control section 11 has an oxygen addition mechanism 112 which adds oxygen to the liquid 1, and a hydrogen addition mechanism 122 which adds hydrogen to the liquid 1. The liquid 1 is supplied to the oxygen addition mechanism 112 from an un-illustrated tank of the liquid supply section 10 via a liquid flow tube 113. The oxygen addition mechanism 112 adds oxygen to the supplied liquid 1, and then the liquid 1 flows into the supply tube 10A via a liquid flow tube 110 and a control valve 111. Similarly, the liquid 1 is supplied to the hydrogen addition mechanism 122 from the un-illustrated tank of the liquid supply section 10 via a liquid flow tube 123. The hydrogen addition mechanism 122 adds hydrogen to the supplied liquid 1, and then the liquid 1 flows into the supply tube 10A via a liquid flow tube 120 and a control valve 121. Further, a liquid supply tube 130 is connected to the supply tube 10A via a control valve 131. The other end of the liquid supply tube 130 is directly connected to the un-illustrated tank of the liquid supply section 10. Opening or closing the control valves 111, 121 and 131 determines as to the liquid 1 is supplied to the supply tube 10A via which one of the liquid supply tubes 110, 120 and 130; and the opening and closing of these control valves are controlled by the controller CONT.

An ultrasonic wave generation device 140 which applies an ultrasonic wave to the liquid 1 flowing therethrough is provided to be adjacent to the supply tube 10A. The ultrasonic wave generation device 140 is an ultrasonic wave generation device capable of applying an ultrasonic wave (mega-sonic) of which frequency is approximately 1 MHz to the liquid 1. An oxidation-reduction potential meter (ORP meter) 141 which measures the oxidation-reduction potential of the liquid 1 flowing inside the supply tube 10A is provided on the supply tube 10A at a portion thereof located downstream of the ultrasonic wave generation device 140, and measurement result by the ORP meter 141 is outputted to the controller CONT. A control valve 142 which switches the liquid 1 between being supplied to the liquid immersion area AR2 and being discharged to a drainpipe 143 is provided on the supply tube 10A at a portion thereof located downstream of the ORP meter 141. The controller CONT performs control of the switching performed by the control valve 142.

The oxygen addition mechanism 112 used in the first embodiment will be explained below. As shown in FIG. 4, the oxygen addition mechanism 112 is provided with a plurality of hollow fibers 114 through which only gas is transmissive (permeable) but any liquid is not transmissive. The liquid 1 is supplied to the inside of the hollow fibers 114 from the un-illustrated tank of the liquid supply section 10 via the liquid flow tube 113. The supplied liquid 1 passes through the inside of the hollow fibers 114, and then flows into the liquid flow tube 110. On the other hand, oxygen is supplied to the oxygen addition mechanism 112 from an un-illustrated oxygen gas supply source (oxygen cylinder) via an oxygen supply tube 115. The supplied oxygen passes outside of the hollow fibers 114, and is discharged out of the oxidation-reduction potential (ORP) control section 11 via an oxygen discharge tube 116. At this time, the oxygen outside the hollow fibers 114 passes through the hollow fibers 114 due to its own pressure, and moves to the inside of the hollow fibers 114. Then, the oxygen is dissolved into the liquid 1 passing through the inside of the hollow fibers 114.

Similarly, the hydrogen addition mechanism 122 used in the first embodiment will be explained below. As shown in FIG. 4, a plurality of hollow fibers 124 through which only gas is permeable but any liquid is not permeable is provided inside the hydrogen addition mechanism 122. The liquid 1 is supplied to the inside of the hollow fibers 124 from the un-illustrated tank of the liquid supply section 10 via the liquid flow tube 123. The supplied liquid 1 passes through the inside of the hollow fibers 124, and then flows into the liquid flow tube 120. On the other hand, hydrogen is supplied to the hydrogen addition mechanism 122 from an un-illustrated hydrogen gas supply source (hydrogen cylinder) via a hydrogen supply tube 125. The supplied hydrogen passes outside of the hollow fibers 124, and is discharged out of the oxidation-reduction potential (ORP) control section 11 via a hydrogen discharge tube 126. At this time, the hydrogen outside the hollow fibers 124 passes through the hollow fibers 124 due to its own pressure, and moves to the inside of the hollow fibers 124. Then, the hydrogen is dissolved into the liquid 1 passing through the inside of the hollow fibers 124.

Next, explanations will be given about a specific example of a method for controlling the oxidation-reduction potential. First, an explanation will be given about a control method for increasing the oxidation-reduction potential. As described above, oxygen is dissolved, at a higher concentration than that in pure water in a normal state, in the liquid 1 flowing through the liquid flow tube 110 via the oxygen addition mechanism 112. In a state that the control valves 121 and 131 are closed, the control valve 111 is opened to allow the liquid 1 flowing through the liquid flow tube 110 to flow into the supply tube 10A. At this time, the ultrasonic wave generation device 140 is activated to apply mega-sonic to the liquid 1 in which the oxygen is dissolved.

By the mega-sonic, a part of water molecules (H₂O) in the liquid 1 is dissociated into hydrogen radicals (H•) and hydroxyl radicals (OH•) (Formula (1)); and oxygen molecules (O₂) dissolved in the liquid 1 immediately react with the hydrogen radicals (H•) to form water molecules (H₂O) (Formula (2)). Formula (1) and Formula (2) are represented as Formula (3). In a case that the mega-sonic is applied to the liquid 1 in a state that the oxygen is dissolved in the liquid 1, it is appreciated from Formula (3) that there are excessive hydroxyl radicals (OH•) with a strong oxidation power. As a result, the oxidation-reduction potential of the liquid 1 is increased. The ORP meter 141 measures the oxidation-reduction potential of the liquid 1 in the supply tube 10A, and outputs the measurement result to the controller CONT. The controller CONT controls the amount of oxygen to be added to the liquid 1 such that the measurement value of the oxidation-reduction potential becomes a preset value (set value). The controller CONT controls the control valve 142 so that the liquid 1 is discharged to the drainpipe 143 in a case that the oxidation-reduction potential of the liquid 1 is different from the set value, or that the liquid 1 is supplied to the supply tube 10A in a case that the oxidation-reduction potential of the liquid 1 is same as the set value.

[Chemical Formula 1]

H₂O→H•+OH• (1)

[Chemical Formula 2]

O₂+4H•2H₂O (2)

[Chemical Formula 3]

2H₂O+O₂→4OH• (3)

Next, an explanation will be given about a control method for decreasing the oxidation-reduction potential. As described above, hydrogen is dissolved in the liquid 1 flowing through the liquid flow tube 120. In a state that the control valves 111 and 131 are closed, the control valve 121 is opened to allow the liquid 1 flowing through the liquid flow tube 120 to flow into the supply tube 10A. Then, the ultrasonic wave generation device 140 is activated to apply the mega-sonic to the liquid 1 in which the hydrogen is dissolved.

By the mega-sonic, a part of water molecules (H₂O) in the liquid 1 is dissociated into hydrogen radicals (H•) and hydroxyl radicals (OH•) (Formula (1)), and hydrogen molecules (H₂) dissolved in the liquid 1 immediately react with the hydroxyl radicals (OH•) to form water molecules (H₂O) (Formula (4)). Formula (1) and Formula (4) are represented as Formula (5). In a case that the mega-sonic is applied to the liquid 1 in which hydrogen is dissolved, it is appreciated from Formula (5) that there are excessive hydrogen radicals (H•) with a strong reduction power. As a result, the oxidation-reduction potential of the liquid 1 is decreased. The ORP meter 141 measures the oxidation-reduction potential of the liquid 1 in the supply tube 10A, and outputs the measurement result to the controller CONT. The controller CONT controls the amount of hydrogen to be added to the liquid 1 such that the measurement result of the oxidation-reduction potential becomes a preset value (set value). The controller CONT controls the control valve 142 so that the liquid 1 is discharged to the drainpipe 143 in a case that the oxidation-reduction potential of the liquid 1 differs from the set value, or that the liquid 1 is supplied to the supply tube 10A in a case that the oxidation-reduction potential of the liquid 1 is equal to the set value.

[Chemical Formula 4]

H₂+2OH·→2H₂O (4)

[Chemical Formula 5]

H₂→2H• (5)

Note that in a case that pure water in the normal state is supplied to the supply tube 10A without performing any control of the oxidation-reduction potential, the control valve 131 is opened in a state that the control valves 111 and 121 are closed so as to supply the liquid 1 flowing through the liquid flow tube 130 to the supply tube 10A. At this time, it is not necessary to use the ultrasonic wave generation device 140 for the purpose of applying the mega-sonic.

As explained above, the mega-sonic used in the first embodiment is an ultrasonic wave having a special function of dissociating a water molecule into a hydrogen radical (H•) and a hydroxyl radical (OH•). On the other hand, ordinary ultrasonic waves is only capable of transmitting vibration to water, but not capable of dissociating a water molecule. Since the vibration of ordinary ultrasonic waves rapidly expands and contracts water molecules, the air contained in water is allowed to become air bubbles. In a cleaning using the ordinary ultrasonic waves, contaminant is removed from an object to be cleaned (cleaning object) with the impact generated by burst of those air bubbles, and thus is greatly different from the cleaning mechanism (to be described later on) of the first embodiment. From this point of view, the mega-sonic used in the first embodiment is distinguished from the ordinary ultrasonic waves. In particular, the mega-sonic used in the first embodiment can have a frequency in a range of 0.8 MHz to 2 MHz. In the first embodiment, for example, it is possible to use the mega-sonic of 998 kHz.

Further, in the first embodiment, the oxidation-reduction potential (ORP) control section 11 performs the above-described operation for pure water, thereby making it possible to produce a liquid having an oxidation-reduction potential which is lower than that of pure water, and another liquid having an oxidation-reduction potential higher than that of pure water. The term “pure water (purified water)” used herein refers to, for example, super-pure water which meets the guideline issued from ITRS (International Technology Roadmap for Semiconductor) and in which each of hydrogen radical, hydroxyl radical, hydrogen peroxide and ozone is contained at an amount of less than 1 ppm.

### [Exposure Method]

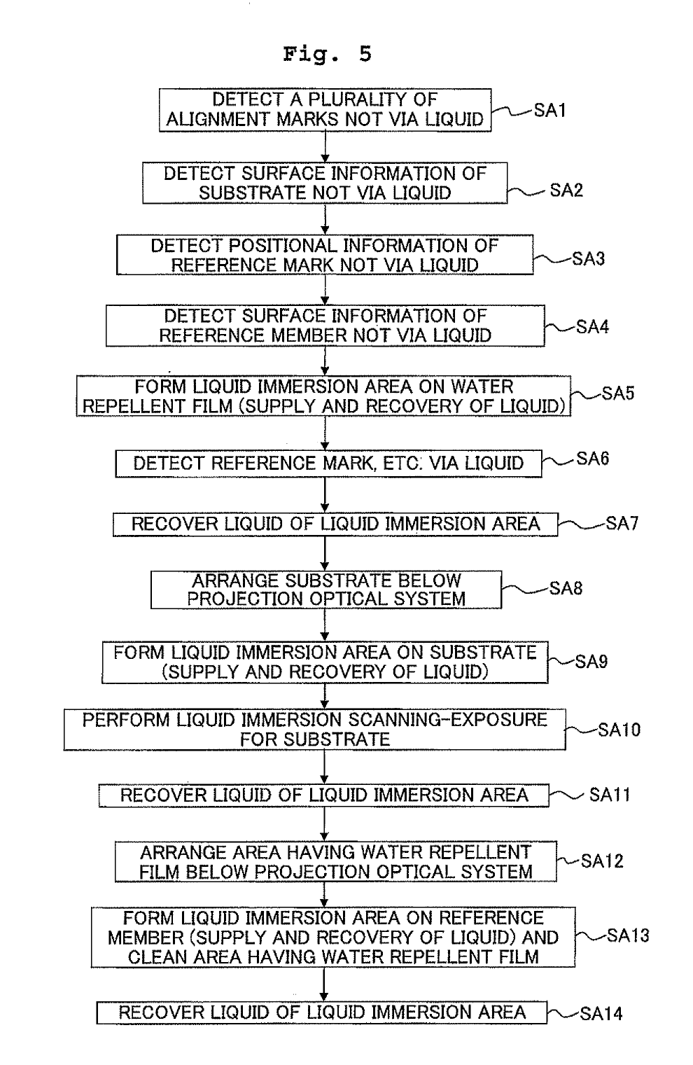

An explanation will be given about a procedure of using the exposure apparatus EX to expose the substrate P with the pattern of the mask M, with reference to the flow chart shown in FIG. 5.

### [Measuring Step]

Before supplying the liquid 1 from the liquid supply section 10, a measuring step is performed at first in a state that the liquid 1 is not present on the substrate P. The controller CONT causes the X-Y stage 53 to move while monitoring the output of the laser interferometer 56 such that the optical axis AX of the projection optical system PL moves along a broken-line arrow 43 in FIG. 2. During the movement of the X-Y stage 53, the substrate alignment system 5 detects, not via the liquid 1, a plurality of alignment marks (not shown) formed on the substrate P according to shot areas S1 to S11 (step SA1). Further, when the substrate alignment system 5 detects the alignment marks, the X-Y stage 53 is stopped. As a result, the positional informations of the respective alignment marks are measured within the coordinate system defined by the laser interferometer 56. Furthermore, the substrate alignment system 5 can detect all of the alignment marks on the substrate P or can detect only a part of the alignment marks.

Moreover, during the movement of the X-Y stage 53, the focus detection system 4 detects surface information of the substrate P not via the liquid 1 (step SA2). The focus detection system 4 detects the surface information for each of all the shot areas S1 to S11 on the substrate 2; and the controller CONT stores the detection result while corresponding the detection result with the position of the substrate P in the scanning direction (the X-axis direction). Note that it is also possible to perform the detection of surface information by the focus detection system 4 only for a part of the shot areas.

When the detection of the alignment marks of the substrate P and the detection of the surface information of the substrate P are completed, the controller CONT causes the X-Y stage 53 to move such that the detection area of the substrate alignment system 5 is positioned on the reference member 7. The substrate alignment system 5 detects the reference mark PFM on the reference member 7, and measures the positional information of the reference mark PFM within the coordinate system defined by the laser interferometer 56 (step SA3).

With the completion of the detecting process of the reference mark PFM, the positional relationships between the reference mark PFM and each of the plurality of alignment marks on the substrate P, namely the positional relationships between the reference mark PFM and each of the plurality of shot areas S1 to S11 on the substrate P are consequently determined. Further, the reference mark PFM and the reference mark MFM are in a predetermined positional relationship, and thus the positional relationships between the reference mark MFM and each of the plurality of shot areas S1 to S11 on the substrate P within the X-Y plane are consequently determined.

Further, before or after the substrate alignment system 5 detects the reference mark PFM, the controller CONT causes the focus detection system 4 to detect the surface information of the surface (reference surface) of the reference member 7 (step SA4). With the completion of the detecting process of the surface of the reference member 7, a relationship between the surface of the reference member 7 and the surface of the substrate P is consequently determined.

Next, the controller CONT moves the X-Y stage 53 so that the mask alignment system 6 can detect the reference mark MFM on the reference member 7. In this state, the end portion of the projection optical system PL faces the reference member 7. Then, the controller CONT causes the liquid supply section 10 to start supply of the liquid 1 and causes the liquid recovery section 30 to start recovery of the liquid 1 so as to locally fill a space between the projection optical system PL and the reference member 7 with the liquid 1, thereby forming the liquid immersion area AR2 (step SA5).

At this time, the controller CONT controls the oxidation-reduction potential (ORP) control section 11 to decrease the oxidation-reduction potential of the liquid 1 which forms the liquid immersion area AR2. In the first embodiment, it is possible to control the oxidation-reduction potential of the liquid 1 to be −0.4 V. Any metal elution into the liquid 1 means the ionization of metal and thus oxidization of metal. Since the liquid 1 having a decreased oxidation-reduction potential has a low oxidation power (high reduction power), the metal elution is suppressed. In particular, in a case that the liquid 1 having an oxidation-reduction potential of not more than +0.4 V, more preferably, having an oxidation-reduction potential in a range of 0 to −0.4 V is used in this step, it is possible to efficiently prevent the degradation of the reference mark MFM and reference mark PFM which would be otherwise caused due to the elution of chromium, and to prevent the liquid 1 itself from being contaminated due to the eluted chromium.

Next, the controller CONT detects the reference mark MFM with the mask alignment system 6 via the mask M, the projection optical system PL and the liquid 1 (step SA6). With this, the position of the mask M within the X-Y plane, namely the information regarding projection position of the pattern image of the mask M, is consequently detected by using the reference mark MFM and via the projection optical system PL and the liquid 1.

When the measuring process as described above is completed, the controller CONT causes the liquid supply section 10 to stop the liquid supply operation of supplying the liquid 1 onto the reference member 7. On the other hand, the controller CONT causes the liquid recovery section 30 to continue the liquid recovery operation of recovering the liquid 1 on the reference member 7 for a predetermined period of time (step SA7). Then, after the predetermined period of time has elapsed, the controller CONT stops the recovery operation by the liquid recovery section 30. Note that since the surface of the reference member 7 is water-repellent, the liquid 1 does not remain on the reference member 7.

Next, as necessary, the uneven illuminance sensor 138 is used to measure the illuminance distribution. First, the controller CONT moves the X-Y stage 53 so that the projection optical system PL faces or is opposite to the plate member 138A of the uneven illuminance sensor 138. In this state, the liquid is filled in a space between the projection optical system PL and the plate member 138A, while moving the pinhole 138P at a plurality of positions within the irradiation area onto which the exposure light is irradiated, and the illuminance of the exposure light is measured at each of the positions to obtain (measure) the illuminance distribution (uneven illuminance). At this time, the controller CONT controls the oxidation-reduction potential (ORP) control section 11 to decrease the oxidation-reduction potential of the liquid 1 which forms the liquid immersion area AR2, in a similar manner as in the detection of the reference mark. In the first embodiment, it is possible to control the oxidation-reduction potential of the liquid 1 to be −0.4 V. With this, it is possible to suppress the elution of the chromium film formed on the plate member 138A, and to prevent the liquid 1 itself from being contaminated at the same time.

After the completion of the illuminance distribution measurement, the controller CONT causes the liquid supply section 10 to stop the operation of supplying the liquid 1 onto the plate member 138A. On the other hand, the controller CONT causes the liquid recovery section 30 to continue the operation of recovering the liquid 1 on the plate member 138A for a predetermined period of time; and then the controller CONT causes the liquid recovery section 30 to stop the recovery operation. Note that since the surface of the plate member 138A is water-repellent, the liquid 1 does not remain on the plate member 138A.

Note that during a period of time during which the controller CONT is detecting the reference mark MFM, etc. via the liquid 1, it is also possible to stop the operation of the ultrasonic wave generation device 140. By doing so, it is possible to prevent the measuring device, etc. from being influenced by the vibration accompanying with the ultrasonic wave generation in the liquid 1.

### [Exposure Step]

Next, in order to expose each of the shot areas S1 to S11 on the substrate P, the controller CONT moves the X-Y stage 53 so that the projection optical system PL faces the substrate P (step SA8). After the projection optical system PL is made to face the substrate P, the controller CONT drives the liquid supply section 10 to start the operation of supplying the liquid onto the substrate P. The liquid 1, fed out from the liquid supply section 10 to form the liquid immersion area AR2, flows through the supply tube 10A and then is supplied onto the substrate P via the nozzle member 70, thereby forming the liquid immersion area AR2 in the space between the projection optical system PL and the substrate P. The liquid 1 supplied on the substrate P forms the liquid immersion area AR2 locally on the substrate P such that the liquid immersion area AR2 has a range which is greater at least than the projection area AR1. Further, the controller CONT controls the liquid recovery section 30 to perform the operation of recovering the liquid on the substrate P, in parallel with performing the operation of supplying the liquid 1 by the liquid supply section 10 (step SA9). At this time, the controller CONT supplies, as the liquid 1, ordinary pure water without controlling the oxidation-reduction potential (ORP) thereof, from the liquid supply section 10 to the liquid immersion area AR2. The oxidation-reduction potential of the liquid 1 at this time is presumed to be approximately +0.5 V.

Then, each piece of the information obtained in the above measuring process is used to subject each of the shot areas S1 to S11 on the substrate P to the scanning exposure (step SA10). Namely, during the scanning exposure for each of the shot areas, the mask M is positioned with respect to each of the shot areas S1 to S11 on the substrate P, based on the information of the positional relationship between the reference mark PFM and each of the shot areas S1 to S11 obtained before supplying the liquid 1 and based on the information of projection position of the pattern image of the mask M obtained by using the reference mark MFM after supplying the liquid 1.

Further, during a period of time during which the scanning exposure is being performed for each of the shot areas S1 to S11, the positional relationship is adjusted between the surface of the substrate P and the image plane formed via the liquid 1 based on the surface information of the substrate P obtained before supplying the liquid 1, without using the focus detection system 4. Alternatively, it is also possible to detect the surface information of the substrate P by using the focus detection system 4 during the scanning exposure, without obtaining the surface information of the substrate P before supplying the liquid 1, and to adjust the positional relationship between the surface of the substrate P and the image plane formed via the liquid 1, based on the detected surface information of the substrate P.

When the scanning exposure of each of the shot areas S1 to S11 on the substrate P is completed, the controller CONT stops the liquid supply by the liquid supply section 10, and uses the liquid recovery section 30 to recover the liquid 1 present under the projection optical system PL (step SA11).

### [Cleaning Step]

After (or before) the liquid immersion exposure is completed, the controller CONT moves the substrate stage PST to arrange the reference member 7 at a position below or under the projection optical system PL in order to clean the reference member 7 (step SA12). Then, the controller CONT drives the liquid supply section 10 and the liquid recovery section 30 to form the liquid immersion area AR2 in a space between the projection optical system PL and the reference member 7. The surface of the reference member 7 is cleaned by the liquid 1 in the liquid immersion area AR2 formed on the reference member 7 (step SA13). Further, at the same time, it is also possible to clean the optical element 2 at the end of the projection optical system PL and the nozzle member 70 disposed in the vicinity of the optical element 2.

At this time, the controller CONT controls the oxidation-reduction potential (ORP) control section 11 to increase the oxidation-reduction potential of the liquid 1 which forms the liquid immersion area AR2. In the first embodiment, it is possible to control the oxidation-reduction potential of the liquid 1 to be +1.0 V. A liquid with a high oxidation-reduction potential has a strong oxidation power, and thus readily dissolves organic substance and metal. In a case that the reference member 7 is cleaned by a liquid with a high oxidation-reduction potential, then any organic contaminant adhering to the surface of the reference member 7 is oxidized, decomposed into small molecules such as carbon dioxide, water, etc., and is removed, while any contaminant derived from chromium is oxidized (ionized), dissolved, and removed. The contaminant derived from chromium is hydrophilic chromic oxide, chromium hydroxide, etc. By removing these contaminants (substances), it is possible to maintain the surface of the reference member 7 to be water-repellent. In particular, from the viewpoint of removing organic contaminant, it is possible to control the oxidation-reduction potential of the liquid 1 to be in a range of +0.6 V to +1.2 V.

In the first embodiment, any ultraviolet light such as the exposure light, etc., is not irradiated in the cleaning of the surface of the reference member 7. With this, even when the liquid 1 with an increased oxidation-reduction potential is used, the chromium film is still prevented from being eluted into the liquid 1. The present inventors found out through the experiments that, when ultraviolet light such as the exposure light, etc., is irradiated in a state that the immersion liquid is present on the surface of the reference member 7, the chromium film positioned below the water repellent film is eluted into the immersion liquid. The inventors conducted an experiment in which an area only making contact with the liquid 1 and another area making contact with the liquid 1 and also irradiated with the exposure light were formed on a test sample having a chromium film and a water repellent film formed on the chromium film. When these areas were compared after the experiment, regarding the area which was not irradiated with the exposure light, hardly any decrease was observed in the chromium film thickness, whereas there was decrease in the chromium film thickness regarding the area irradiated with the exposure light. Accordingly, in the first embodiment, the liquid 1 with an increased oxidation-reduction potential is used to clean the surface of the reference member 7 without performing irradiation with ultraviolet light, thereby making it possible to prevent the elution of chromium while removing only the contaminant adhering to the surface of the reference member 7 through decomposition and dissolution, and to maintain the surface to be water-repellent.

After the completion of the cleaning process, the controller CONT stops the liquid supply by the liquid supply section 10, and uses the liquid recovery section 30 to recover the liquid 1 present below the projection optical system PL (step SA14).

Next, with a method similar to that for cleaning the surface of the reference member 7, the surface of the auxiliary plate 57 and the surface of the plate member 138A which constructs a part of the uneven illuminance sensor 138 are cleaned. Since a chromium film is provided on the surface of the plate member 138A, the cleaning is performed without performing irradiation with ultraviolet light such as the exposure light, etc., so as to prevent the elution of the chromium film.

### Second Embodiment

An exposure apparatus which is similar as that in the first embodiment is used to perform a measuring step (SA1 to SA7) and the exposure step (SA8 to SA11) in a similar manner as those performed in the first embodiment, except that the oxidation-reduction potential of the liquid 1 is increased in the exposure step. In the second embodiment, it is possible to control the oxidation-reduction potential to be +1.0 V in the exposure step. Note that step of SA12 to SA14 is not performed in the second embodiment.

A liquid having a high oxidation-reduction potential readily dissolves organic substance and metal. Since the second embodiment uses a liquid 1 of which oxidation-reduction potential is increased in the exposure step, it is possible to clean a portion which makes contact with the liquid 1 in the exposure step such as the auxiliary plate 57, etc., thereby making it possible to maintain the water repellency of the portion which makes contact with the liquid 1. In the second embodiment, it is possible to expose a substrate and clean the area (water-repellent area) having the water repellent film, at the same time. Therefore, although the cleaning step of SA12 to SA14 is not performed in the second embodiment, it is possible to perform, as necessary, the cleaning step of SA12 to SA14 before or after the exposure step. Further, in the second embodiment, it is also possible to clean, at the same time, the optical element 2 which is arranged at the end of the projection optical system PL and makes contact with the liquid and the nozzle member 70 which is arranged in the vicinity of the optical element 2 and makes contact with the liquid 1.

### Third Embodiment

An exposure apparatus which is similar to that used in the first embodiment is used to perform an operation similar as that in the first embodiment, except that the oxidation-reduction potential of the liquid 1 is decreased in the exposure step. Namely, in the third embodiment, the oxidation-reduction potential is decreased not only in the measuring step but also in the exposure step. In view of the control, the oxidation-reduction potential in the exposure step is preferably −0.4 V, similarly to that oxidation-reduction potential in the measuring step.

In the third embodiment, since the oxidation-reduction potential of the liquid 1 is decrease in both of the measuring step and the exposure step, is not necessary to significantly change the oxidation-reduction potential of the liquid 1 when switching from the measuring step to the exposure step, thereby making it possible to reduce the loss time for adjusting (changing) the oxidation-reduction potential and thus to prevent the total process time from being increased. With this, it is possible to improve the throughput of exposing the substrate, in addition to the effect of making it possible to suppress the elution of the chromium film formed on the plate member 138A, in a similar manner as in the first and second embodiments. Note that in the third embodiment, it is also possible that the cleaning step of SA12 to SA14 is not performed.

### Forth Embodiment

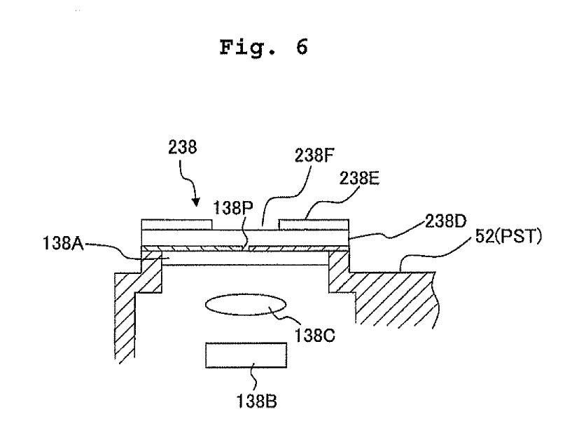

In the forth embodiment, an exposure apparatus similar to that used in the first embodiment is used to perform the measuring step, exposure step and cleaning step in a similar manner as in the first embodiment, except that an uneven illuminance sensor 238 shown in FIG. 6 is provided on the exposure apparatus, instead of using the uneven illuminance sensor 138 shown in FIG. 3. Note that it is also possible not to perform the cleaning step of SA12 to SA14.

In the uneven illuminance sensor 138 of first embodiment, the water repellent film containing the fluororesin (not shown in FIG. 3) is provided on the thin film (light-shielding film) 138B containing chromium. On the other hand, in the uneven illuminance sensor 238 of the fourth embodiment, an insulation film 238D and a water repellent film 238E are stacked in this order on a thin film (light-shielding film) containing chromium. Other than this, the uneven illuminance sensor 238 has a construction similar to that of the uneven illuminance sensor 138 of the first embodiment. For example, silicon dioxide (SiO₂) through which UV light is transmitted as detection light can be used for the insulation film 238D. Similarly as the first embodiment, a fluororesin can be used for the water repellent film 238E. Further, the water repellent film 238E has an opening 238F formed at a center portion thereof. In this manner, it is also possible that any fluororesin as the water repellent film is not provided on the area which is irradiated with the UV light for the purpose of preventing the fluororesin from being degraded due to the irradiation with the UV light. Provided that the opening 238F is a minute area, the water repellency can be maintained by the liquid surface tension.

Similarly as the first to third embodiments, the fourth embodiment is capable of suppressing the elution of the chromium film formed on the plate member 138A and of improving the tight contact performance between the metallic film and the water repellent film, thereby enhancing the durability of the uneven illuminance sensor 238.

Note that in the fourth embodiment, the single-layer thin film 138B containing chromium as the metallic film is provided on the plate member 138A. It is possible, however, to use a multilayer metallic film having two or more layers, instead of using the single-layer metallic film. In such a case, the insulation film 238D and the water repellent film 238E are stacked on the multilayer metallic film 138E having two or more layers.

As explained above regarding the first to fourth embodiments, the oxidation-reduction potential of the liquid used in the measuring step (SA1 to SA7) and/or the exposure step (SA8 to SA11) is controlled to a predetermined value, thereby making it possible to prevent the chromium film from being eluted in the exposure apparatus and further to remove any organic contaminant and chromium contaminant adhering to the surface of the area which makes contact with the immersion liquid.

Although the present teaching has been explained by way of the embodiments, the present teaching is not limited to those embodiments. Although the cleaning step of SA12 to SA14 is performed after (or before) the exposure step in the first and third embodiments, the cleaning step of SA12 to SA14 can be performed every time after exposure of one or more substrates is completed. By doing so, it is possible to prevent any increase in takt time (cycle time) accompanying with the change in the oxidation-reduction potential and to increase the throughput. In the above embodiments, chromium is used as the material of the light-shielding film (metallic film). However, other than chromium, it is also possible to use such materials including oxides and nitrides as Ti, Zr, C, Si, W, Ta, Mo, SiOₓ, SiN_{X}, ZrOₓ, ZrNₓ, TaOₓ, TaNₓ, CrOₓ, CrNₓ, etc.

Further, in the control of the oxidation-reduction potential of the liquid 1 in the first to fourth embodiments, oxygen is made to dissolve into the liquid 1 via the hollow fiber 114 by allowing the liquid 1 to flow inside of the hollow fiber 114 and allowing oxygen to flow outside the hollow fiber 114, or hydrogen is made to dissolve into the liquid 1 via the hollow fiber 124 by allowing the liquid 1 to flow inside of the hollow fiber 124 and allowing hydrogen to flow outside the hollow fiber 124. On the contrary, it is also possible to dissolve oxygen into the liquid 1 by allowing the liquid 1 to flow outside of the hollow fiber 114 and allowing oxygen to flow inside the hollow fiber 114, or to dissolve hydrogen into the liquid 1 by allowing the liquid 1 to flow outside of the hollow fiber 124 and allowing hydrogen to flow inside the hollow fiber 124. Further, it is also possible to dissolve oxygen or hydrogen into the liquid 1 by directly blowing oxygen or hydrogen into the liquid 1, without using any hollow fibers.

Further, in the first to fourth embodiments, the oxidation-reduction potential of the liquid 1 is controlled by controlling the amount of oxygen and the amount of hydrogen added to the liquid 1. However, instead of this or in addition to this, it is also possible to control the frequency, power, time, etc. of the mega-sonic irradiating onto the liquid 1 to which oxygen or hydrogen is added.

Further, in the first to fourth embodiments, the oxidation-reduction potential of the liquid 1 is adjusted by adding oxygen or hydrogen and then applying the mega-sonic to the liquid 1. However, the adjustment of the oxidation-reduction potential of the liquid 1 can also be performed by another method which does not apply the mega-sonic. For example, the method for decreasing the oxidation-reduction potential is exemplified by a method of adding hydrogen after removing oxygen from the liquid 1. Further, the method for increasing the oxidation-reduction potential is exemplified by a method of adding ozone.

As the method for decreasing the oxidation-reduction potential, for example, a degassing device having a large number of hollow fibers which are arranged inside the degassing device and through which only gas is permeable and any liquid is not permeable is used to perform the following process: the inside of the hollow fibers are evacuated and the liquid 1 is allowed to flow in a portion located around the hollow fibers to thereby move oxygen from the liquid 1, via the hollow fibers, into the inside of the hollow fibers so that oxygen is removed from the liquid 1; next, the liquid 1 from which oxygen has been removed is made to pass through the hydrogen addition mechanism 122 shown in FIG. 4, and then hydrogen is added to the liquid 1. As the method for increasing the oxidation-reduction potential, for example, ozone is used in the hydrogen addition mechanism 122 shown in FIG. 4, instead of using oxygen, and ozone is added to the liquid 1. Note that it is possible to increase the oxidation-reduction potential with such a control method in which ozone is added and then the mega-sonic is applied.

In the first embodiment, the respective steps are performed according to the flowchart shown in FIG. 5 in the order of the measuring step (SA1 to SA7), the exposure step (SA8 to SA11) and the cleaning step (SA12 to SA14). Also in the second to fourth embodiments, the respective steps are performed according to the flowchart shown in FIG. 5 in the order of the measuring step (SA1 to SA7) and the exposure step (SA8 to SA11). However, it is possible to reverse or exchange the order of performing the steps as necessary, and to change the number of time for performing each of the steps. For example, the cleaning step can be performed before performing the exposure step, or can be performed before performing the measuring step. Alternatively, it is possible to perform the measuring step one time, and then to perform the exposure step a plurality of times, to perform the cleaning process, and then to perform the exposure process a plurality of times again.

In the second embodiment, the oxidation-reduction potential of the liquid 1 is decreased in the measuring step (SA1 to SA7). However, it is not necessarily indispensable to decrease the oxidation-reduction potential in the measuring step. By increasing the oxidation-reduction potential of the liquid 1 in the exposure step (SA8 to SA11), the organic contaminant and chromium contaminant adhering to the area which makes contact with the immersion liquid are removed. As a result, it is possible to maintain the exposure accuracy of the immersion exposure apparatus.

According to the above embodiments, the oxidation-reduction potential of the liquid used in the measuring step and/or the exposure step is controlled to be a predetermined value to thereby remove an organic contaminant and chromium contaminant adhering to the area which makes contact with the immersion liquid. As a result, it is possible to maintain the exposure accuracy of the immersion exposure apparatus. Specifically, for example, the oxidation-reduction potential of the liquid used in the exposure step and/or the cleaning step is removed so as to increase the oxidation power of the liquid, thereby removing a contaminant adhering to the area contacting with the immersion liquid in the exposure apparatus. With this, it is possible to maintain the water repellency of the area.

According to the present teaching, by controlling the oxidation-reduction potential, of the liquid used in the measuring step and/or the cleaning step, to a predetermined value, the area which has the water repellency and which contacts with the liquid is cleaned to maintain the water repellency of the area. Further, any elution from the chromium film used in the immersion exposure apparatus is prevented to thereby maintain the water repellent performance of the area having the water repellency and contacting with the area. As a result, it is possible to maintain the exposure accuracy of the immersion exposure apparatus.

1. An exposure method for exposing a substrate by using an immersion exposure apparatus provided with a water-repellent area which has a water repellent film therein and which is at least a part of an area configured to make contact with a liquid so as to irradiate an exposure light onto the substrate via the liquid, the exposure method comprising:
a measuring step of performing a measurement via the liquid with respect to at least a part of the water-repellent area having the water repellent film; and
an exposure step of irradiating the exposure light onto the substrate via the liquid,
wherein in the measuring step and/or the exposure step, oxidation-reduction potential of the liquid is controlled to a predetermined value.

2. The exposure method according to claim 1, further comprising a cleaning step of cleaning the water-repellent area having the water repellent film by using the liquid.

3. The exposure method according to claim 1, wherein the oxidation-reduction potential of the liquid used in the measuring step is controlled to be lower than the oxidation-reduction potential of the liquid used in the exposure step.

4. The exposure method according to claim 2, wherein the oxidation-reduction potential of the liquid used in the measuring step is controlled to be lower than the oxidation-reduction potential of the liquid used in the cleaning step.

5. The exposure method according to claim 2, wherein the oxidation-reduction potential of the liquid used in the cleaning step is controlled to be higher than the oxidation-reduction potential of the liquid used in the exposure step.

6. The exposure method according to claim 1, wherein the water repellent film contains a fluororesin, and has an angle of contact with water in a range of 100 degrees to 115 degrees.

7. The exposure method according to claim 1, wherein a chromium film is provided in the water-repellent area which has the water repellent film and for which the measuring step is performed; and the water repellent film is provided on the chromium film.

8. The exposure method according to claim 7, wherein an insulation film is further included between the chromium film and the water repellent film.

9. The exposure method according to claim 1, wherein the liquid is pure water; and the controlling of the oxidation-reduction potential to the predetermined value includes adding oxygen or hydrogen to the pure water and then applying a mega-sonic to the pure water.

10. The exposure method according to claim 9, wherein the controlling of the oxidation-reduction potential to the predetermined value includes increasing the oxidation-reduction potential by increasing hydroxyl radical in the liquid or decreasing the oxidation-reduction potential by increasing hydrogen radical in the liquid.

11. The exposure method according to claim 2, wherein the cleaning step comprises cleaning the water-repellent area having the water repellent film with the liquid, without irradiating ultraviolet light.

12. A cleaning method for cleaning a water-repellent area in an immersion exposure apparatus configured to expose a substrate by irradiating an exposure light onto the substrate via a liquid, the water-repellent area having a water repellent film therein and being at least a part of an area configured to make contact with the liquid,
the cleaning method comprising using the liquid of which oxidation-reduction potential is increased so as to clean the water-repellent area having the water repellent film.

13. The cleaning method according to claim 12, wherein the water repellent film contains a fluororesin, and has a contact angle with water which is in a range of 100 degrees to 115 degrees.

14. The cleaning method according to claim 12, wherein the liquid is pure water; and the increasing of the oxidation-reduction potential includes adding oxygen to the pure water and then applying a mega-sonic to the pure water.

15. The cleaning method according to claim 14, wherein the increasing of the oxidation-reduction potential includes increasing hydroxyl radical in the liquid.

16. The cleaning method according to claim 12, wherein a chromium film is provided in the water-repellent area having the water repellent film, and the water repellent film is provided on the chromium film.

17. The cleaning method according to claim 16, wherein an insulation film is further included between the chromium film and the water repellent film.

18. The cleaning method according to claim 12, further comprising cleaning the water-repellent area having the water repellent film by using the liquid, while exposing the substrate by irradiating the exposure light onto the substrate via the liquid.

19. An exposure apparatus configured to perform the exposure method as defined in claim 1.

20. An exposure apparatus comprising the water-repellent area having the water repellent film, as an object to be cleaned by the cleaning method as defined in claim 12.

21. An exposure apparatus configured to expose a substrate by projecting an image of a pattern onto the substrate via a liquid, the exposure apparatus comprising:
a stage configured to hold the substrate;
an optical element configured to form the image of the pattern on the substrate;
a liquid supply section configured to supply the liquid onto the stage; and
an oxidation-reduction potential control section configured to control oxidation-reduction potential of the liquid to a predetermined value,
wherein at least a part of a surface, of the stage, configured to make contact with the liquid is a water-repellent area having a water repellent film therein.

22. The exposure apparatus according to claim 21, wherein the water repellent film contains a fluororesin, and has a contact angle with water which is in a range of 100 degrees to 115 degrees.

23. The exposure apparatus according to claim 21, wherein a chromium film is provided in at least a part of the water-repellent area having the water repellent film, and the water repellent film is provided on the chromium film.

24. The exposure apparatus according to claim 23, wherein an insulation film is further included between the chromium film and the water repellent film.

25. The exposure apparatus according to claim 21, wherein the liquid is pure water; and
the oxidation-reduction potential control section has an oxygen addition mechanism configured to add oxygen to the pure water and/or a hydrogen addition mechanism configured to add hydrogen to the pure water; and
the exposure apparatus further comprises an ultrasonic wave generation device configured to apply a mega-sonic onto the pure water to which the oxygen or hydrogen is added.

26. An exposure method comprising:
a measuring step of irradiating a light onto a measuring member, which has a base member and a pattern formed of a metal and disposed on a base member, in a state that the measuring member makes contact with a liquid; and
an exposure step of irradiating an exposure light onto a substrate via the liquid;
wherein in the measuring step, the liquid has oxidation-reduction potential which is lower than that of pure water.

27. The exposure method according to claim 26, wherein in the exposure step, the oxidation-reduction potential of the liquid is lower than that of the pure water.

28. The exposure method according to claim 26, wherein the metal includes chromium.

29. The exposure method according to claim 26, wherein the liquid having the oxidation-reduction potential which is lower than that of the pure water contains more hydrogen radical than the pure water.

30. The exposure method according to claim 26, wherein an insulation film and a water repellent film are stacked in this order on the pattern formed of the metal.

31. An exposure method for exposing a substrate by using an immersion exposure apparatus provided with a water-repellent area which has a water repellent film therein and which is at least a part of an area configured to make contact with a liquid so as to irradiate an exposure light onto the substrate via the liquid, the exposure method comprising:
a measuring step of performing a measurement via the liquid with respect to at least a part of the water-repellent area having the water repellent film; and
an exposure step of irradiating the exposure light onto the substrate via the liquid;
wherein in the measuring step, oxidation-reduction potential of the liquid is decreased.

32. An exposure method for exposing a substrate by using an immersion exposure apparatus provided with a water-repellent area which has a water repellent film therein and which is at least a part of an area configured to make contact with a liquid so as to irradiate an exposure light onto the substrate via the liquid, the exposure method comprising:
a measuring step of performing a measurement via the liquid with respect to at least a part of the water-repellent area having the water repellent film; and
an exposure step of irradiating the exposure light onto the substrate via the liquid;
wherein the measuring step uses a liquid of which oxidation-reduction potential has been controlled so as to suppress elution of metal.

33. The exposure method according to claim 31, wherein in the measuring step, the oxidation-reduction potential of the liquid is not more than +0.4 V.

34. The exposure method according to claim 32, wherein in the measuring step, the oxidation-reduction potential of the liquid is not more than +0.4 V.

35. The exposure method according to claim 31, wherein in the measuring step, the liquid makes contact with a portion constructed of a glass and a thin film containing chromium and patterned on a surface of the glass.

36. The exposure method according to claim 32, wherein in the measuring step, the liquid makes contact with a portion constructed of a glass and a thin film containing chromium and patterned on a surface of the glass.

37. The exposure method according to claim 31, wherein the oxidation-reduction potential of the liquid is decreased by increasing concentration of hydrogen radicals in the liquid.

38. The exposure method according to claim 32, wherein the oxidation-reduction potential of the liquid is decreased by increasing concentration of hydrogen radicals in the liquid.
